(19) United States
(12) Patent Application Publication
(10) Pub. No.: US 2026/0026391 A1
(43) Pub. Date: Jan. 22, 2026

(54) SEMICONDUCTOR PACKAGING METHOD INCLUDING FORMING BOND CONNECTIONS WITH SUPPRESSED COPPER OUTDIFFUSION

(71) Applicant: Taiwan Semiconductor Manufacturing Company, LTD., Hsinchu (TW)

(72) Inventor: Mingni Chang, Hsinchu (TW)

(21) Appl. No.: 18/777,891

(22) Filed: Jul. 19, 2024

(51) Int. Cl. H01L 23/00; H01L 25/065

(52) U.S. Cl. CPC H01L 24/05; H01L 24/03; H01L 24/08; H01L 24/02; H01L 25/0657; H01L 2224/02381; H01L 2224/03424; H01L 2224/03464; H01L 2224/05073; H01L 2224/05147; H01L 2224/05541; H01L 2224/05573; H01L 2224/05644; H01L 2224/05647; H01L 2224/05655; H01L 2224/05657; H01L 2224/05666; H01L 2224/05684; H01L 2224/05687; H01L 2224/08145; H01L 2224/08225; H01L 2924/01025; H01L 2924/30101

(57) ABSTRACT

A copper diffusion-suppressing electrical bond between a first semiconductor wafer or chip or interposer and a second semiconductor wafer or chip or interposer includes a first bond pad metal with a first bond pad metal surface disposed on the first semiconductor wafer or chip or interposer, bonded with a second bond pad metal with a second bond pad metal surface disposed on the second semiconductor wafer or chip or interposer. A copper outdiffusion-suppressing coating such as a titanium, cobalt, nickel/gold, or nickel/palladium/gold layer may be disposed on the first copper bond pad metal surface and/or on the second copper bond pad metal surface. The copper of the bond pad metal may be doped with manganese to form a copper outdiffusion-suppressing surface manganese oxide. The bond pad metal may alternatively be tungsten to prevent copper outdiffusion.

### BACKGROUND

The following relates to semiconductor wafer and/or chip stacks such as chip-on-wafer (CoW) packages, wafer-on-wafer (WoW) packages, chip-on-wafer-on-substrate (CoWoS) packages, integrated fan-out (InFO) packages, package-on-package (PoP) packages, system on integrated chips (SoIC) packages, and the like, and to methods of manufacturing and/or assembling same.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates two bond connections between a first semiconductor wafer or chip or interposer and a second wafer or chip or interposer.

FIGS. 2, 3, 4, 5, 6, 7, 8, 9, and 10 illustrate, by way of diagrammatically side sectional views, representative electrical bonds between a first wafer or chip or interposer and a second wafer or chip or interposer, according to various embodiments as described herein.

FIG. 11 diagrammatically illustrates a side sectional view of an electrical bond connecting a through-silicon via in a top wafer or chip or interposer and an aluminum pad of a bottom wafer or chip.

FIG. 12 diagrammatically illustrates a side sectional view of a portion of a top wafer or chip or interposer and a bottom wafer or chip or interposer, and two representative electrical bonds connecting the top and bottom wafers or chips or interposers.

FIG. 13 diagrammatically illustrates a side sectional view of an electrical bond connecting a metallization of a top wafer or chip or interposer and a metallization of a bottom wafer or chip or interposer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor packages are sometimes constructed as semiconductor wafer and/or chip stacks, in which two or more of the semiconductor wafers and/or chips of the stack include integrated circuits (ICs). Some nonlimiting illustrative examples of such packages include: chip-on-wafer (CoW) packages, wafer-on-wafer (WoW) packages, chip-on-wafer-on-substrate (CoWoS) packages, integrated fan-out (InFO) packages, package-on-package (POP) packages, system on integrated chips (SoIC) packages, and the like. In such packages, the ICs on different wafers and/or ICs of the stack are physically and electrically connected together by bonding the mating surfaces of bond pad metal on the respective wafers and/or ICs. In some approaches, two or more semiconductor chips may be bonded to a larger-area semiconductor chip or wafer. In some types of semiconductor wafer or chip stacks, an interposer wafer or chip may be inserted between two semiconductor wafers or chips that contain ICs. The interposer does not itself include any ICs, but the interposer includes one or more metallization layers, such as a metallization stack or stacks forming one or more redistribution layers (RDLs) for routing electrical power and/or signals between the ICs of the two semiconductor wafers or chips. These are merely some nonlimiting illustrative examples of semiconductor wafer and/or chip stacks.

In such semiconductor wafer and/or chip stacks, the bond pad metal is typically formed in and/or embedded in a dielectric material, which may be referred to as intermetal dielectric (IMD) or similar nomenclature. The bond pad metal is typically copper, and connects with a bond pad via that electrically connects the bond pad metal to a metallization layer, to an aluminum pad, or connects with a through-silicon via (TSV) in the case of bond pad metal of an interposer wafer or other configuration in which the bond pad metal is to electrically connect with circuitry on the opposite side of the wafer, chip, or interposer on which the bond pad metal is disposed. In one nonlimiting example, each semiconductor wafer or die has an IC or ICs formed by front end-of-line (FEOL) processing, which is followed by back end-of-line (BEOL) processing to form a stack of metallization layers connected by vias. The BEOL processing includes successive processes of IMD deposition and patterning, metal deposition/patterning or metal plating or the like to form each metallization layer and connecting vias. The topmost metallization layer then includes the bond pad metal and the connecting bond pad vias. The bonding of the bond pad metal of two wafers, chips, and/or interposers may for example employ thermal or thermocompression bonding, ultrasonic bonding, or the like.

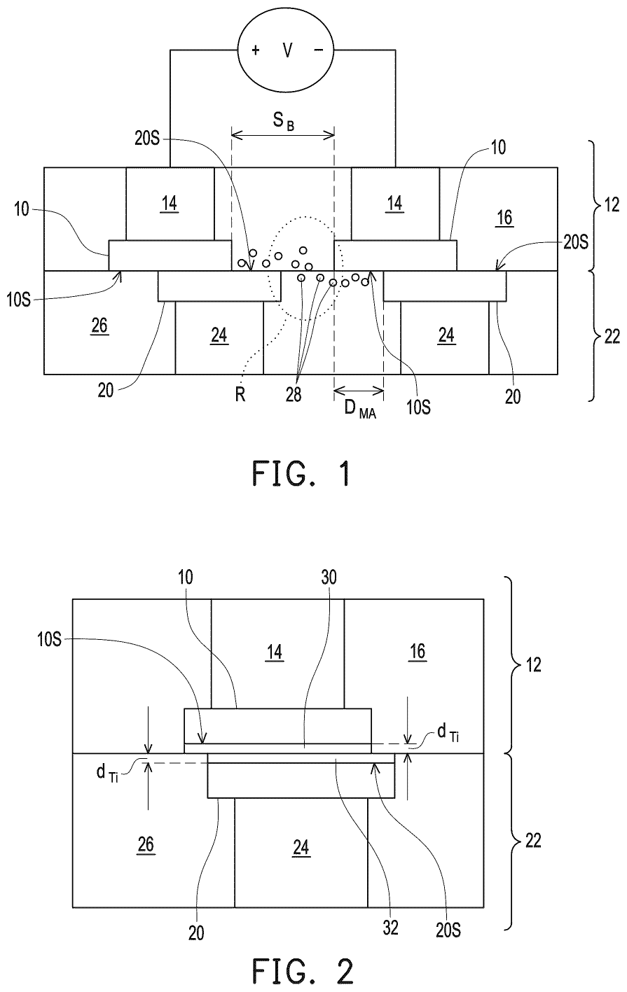

FIG. 1 illustrates two regions of first bond pad metal 10, each with a first bond pad metal surface 10S, formed on a first (illustrative top) semiconductor wafer or chip or interposer 12. First bond pad vias 14 are disposed in the first semiconductor wafer or chip or interposer 12 and connect with respective regions of first bond pad metal 10 on an opposite side from the first bond pad metal surface 10S. The first semiconductor wafer or chip or interposer 12 includes the first bond pad metal 10 and first bond pad vias 14, and further includes a first dielectric material or layer 16. The first bond pad metal 10 and first bond pad vias 14 are disposed in or embedded in the first dielectric material or layer 16, with the first bond pad metal surfaces 10S of the respective regions of first bond pad metal 10 not covered by the first dielectric material or layer 16. The first bond pad metal 10 and first bond metal vias 14 are copper, and the first copper bond pad metal surfaces 10S are copper surfaces. The first dielectric material or layer 16 may, for example, comprise silicon oxynitride (SiON), a high density plasma (HDP) dielectric such as undoped silicate glass (USG), or the like. FIG. 1 only illustrates a portion of the first semiconductor wafer or chip or interposer 12, and it will be appreciated that the first semiconductor wafer or chip or interposer 12 may further include additional components such as (by way of nonlimiting illustrative example) an IC (or array of ICs) fabricated in a silicon wafer or substrate and electrically connected with the first bond pad vias 14 (features not shown) or so forth.

FIG. 1 further illustrates two regions of second bond pad metal 20, each with a second bond pad metal surface 20S, formed on a second (illustrative bottom) semiconductor wafer or chip or interposer 22. Second bond pad vias 24 are disposed in the second semiconductor wafer or chip or interposer 22 and connect with respective regions of second bond pad metal 20 on an opposite side from the second bond pad metal surface 20S. The second semiconductor wafer or chip or interposer 22 includes the second bond pad metal 20 and second bond pad vias 24, and further includes a second dielectric material or layer 26. The second bond pad metal 20 and second bond pad vias 24 are disposed in or embedded in the second dielectric material or layer 26, with the second bond pad metal surfaces 20S of the respective regions of second bond pad metal 20 not covered by the first dielectric material or layer 26. The second bond pad metal 20 and second bond metal vias 24 are copper, and the second copper bond pad metal surfaces 20S are copper surfaces. The second dielectric material or layer 26 may, for example, comprise SiON, a HDP dielectric such as USG, or the like. FIG. 1 only illustrates a portion of the second semiconductor wafer or chip or interposer 22, and it will be appreciated that the second semiconductor wafer or chip or interposer 22 may further include additional components such as (by way of nonlimiting illustrative example) an IC (or array of ICs) fabricated in a silicon wafer or substrate and electrically connected with the second bond pad vias 24 (features not shown) or so forth.

In one approach for fabricating the first copper bond pad via 14 and first copper bond pad metal 10 of the first semiconductor wafer or chip or interposer 12, the first dielectric material or layer 16 is deposited on an IC, metallization layer, or other underlying semiconductor device structure. Openings corresponding to the copper features 10 and 14 are formed by photolithographically controlled etching of the first dielectric material or layer 16. These openings are filled with copper by electroless copper plating, followed by chemical mechanical polishing (CMP) to remove excess copper from the surface of the first dielectric material or layer 16. In some such embodiments, the photolithographically controlled etching and copper deposition can be repeated to form the copper bond pad via 14 and copper bond pad metal 10 with different diameters or other different geometry, and an etch stop layer (not shown) may optionally be employed to control depth of the photolithographically controlled etching. The second copper bond pad via 24 and second copper bond pad metal 20 of the second semiconductor wafer or chip or interposer 22 may be similarly fabricated. The foregoing is merely one nonlimiting illustrative approach for forming these features.

As further illustrated in FIG. 1, the first semiconductor wafer or chip or interposer 12 and the second semiconductor wafer or chip or interposer 22 are bonded together by bonding the first copper bond pad metal surfaces 10S of the regions of first copper bond pad metal 10 and the second copper bond pad metal surfaces 20S of corresponding regions of second copper bond pad metal 20 together to form electrical connection between the first semiconductor wafer or chip or interposer 12 and the second semiconductor wafer or chip or interposer 22. The bonding may, by way of nonlimiting illustrative example, be performed using thermal or thermocompression bonding, ultrasonic bonding, or the like.

For miniaturized semiconductor devices and packages, it is desirable to have a bond spacing S_{B} (indicated in FIG. 1) between adjacent regions of first copper bond pad metal 10 be small. For example, in some packages the bond spacing S_{B} may be 3.5 micron or smaller. For some semiconductor packages it is desirable to have the bond spacing S_{B} be smaller than this, e.g. around one micron or smaller in some contemplated package designs. While the bond spacing S_{B} is labeled and described in the preceding for the regions of first copper bond pad metal 10 of the first semiconductor wafer or chip or interposer 12, it is desired that the regions of second copper bond pad metal 20 of the second semiconductor wafer or chip or interposer 22 be aligned with respective regions of first copper bond pad metal 10, and so the bond spacing S_{B} also applies for the regions of second copper bond pad metal 20. It is also noted that the bond spacing over the pattern of regions of bond pad metal is not necessarily the same for every pair of regions of bond pad metal, and the bond spacing S_{B} should be considered a representative example.

The regions of copper bond pad metal 10 and 20 may be comparable in size to the bond spacing S_{B}, e.g., in one nonlimiting illustrative example each region of bond pad metal 10 and 20 may have a principle dimension (e.g., a diameter) of about 2.5 micron, with each bond pad via 14 and 24 having a principle dimension (e.g., a diameter) of about 1.8 micron. As noted, the regions of first copper bond pad metal 10 should have corresponding regions of second copper bond pad metal 20, so that the first and second wafers or chips or interposers 12 and 22 are bonded together via the mutually aligned regions of copper bond pad metal 10 and 20 on the respective wafers or chips or interposers 12 and 22. In the case of perfect alignment, the first copper bond pad metal surfaces 10S are fully covered by the aligned second copper bond pad metal surfaces 20S, and vice versa.

However, as diagrammatically shown in FIG. 1, in practice there may be some lateral misalignment, e.g., as indicated by a lateral misalignment distance D_{MA} indicated in FIG. 1. The lateral misalignment D_{MA} is not desired, but occurs in semiconductor packaging processes due to process variations. In some cases, the lateral misalignment distance D_{MA} could be 0%˜30% of the width of the bond pad metal 10 (or bond pad metal 20) as lateral tolerance (i.e., acceptable lateral positioning error range). As a consequence of this lateral misalignment, portions of the first copper bond pad metal surfaces 10S are not covered by the (mis) aligned second copper bond pad metal surface 20S, and vice versa. Hence, the non-overlapping portions of the first and second copper bond pad metal surfaces 10S and 20S are exposed to the first and second dielectric material or layers 16 and 26, and particularly to the interface between the first and second dielectric material or layer 16 and 26. As diagrammatically indicated in FIG. 1, this can lead to copper outdiffusion (shown in FIG. 1 by diagrammatically indicated copper atoms or particles 28 in a region R) from the non-overlapping portions of the first and second copper bond pad metal surfaces 10S and 20S into the dielectric material or layers 16 and 26. Such copper outdiffusion can be thermally driven by heat applied during the thermal or thermocompressive bonding process. Due to the relatively close bond spacing S_{B} (e.g., 3.5 micron or less in some embodiments, or one micron or less in some more compact embodiments) the outdiffused copper can increase electrical conductivity in the region R between adjacent regions of copper bond pad metal 10 and 20, and this can lead to low electrical resistance or electrical shorting across the region R of the adjacent regions of copper bond pad metal 10 and 20. This is disadvantageous as it reduces package yield as packages with such low resistance or shorted regions may need to be discarded.

Moreover, even if the region R does not exhibit low electrical resistance or electrical shorting at the time of the bonding, further copper outdiffusion can be driven by operation over time of the completed package. For example, if a voltage difference V indicated in FIG. 1 is applied across the two regions of bond pad metal 10, this produces a corresponding voltage V between these two regions (as well as in corresponding regions of bond pad metal 20) creating an electric field in the region R which can drive copper outdiffusion from the surfaces 10S and 20S into the region R. Such voltage-driven copper outdiffusion can disadvantageously reduce the time-dependent dielectric breakdown (TDDB) of the device.

In embodiments disclosed herein, bond connections with suppressed copper outdiffusion from non-overlapping portions of the bond pad metal surfaces 10S and 20S due to lateral misalignment (e.g., diagrammatically indicated lateral misalignment D_{MA}) are disclosed.

With reference to FIGS. 2-7, in some embodiments suppression of copper outdiffusion is provided by disposing a copper outdiffusion-suppressing coating on the first copper bond pad metal surface 10S and/or on the second copper bond pad metal surface 20S. After disposing the copper outdiffusion-suppressing coating on one or both copper bond pad metal surfaces 10S and/or 20S, the first copper bond pad metal surface 10S and the second copper bond pad metal surface 20S are bonded together, for example using thermal or thermocompressive bonding or ultrasonic bonding, to form an electrical connection between the first semiconductor wafer or chip or interposer 12 and the second semiconductor wafer or chip or interposer 22.

FIG. 2 illustrates, by way of a diagrammatic side sectional view, a representative electrical bond between the first wafer or chip or interposer 12 and the second wafer or chip or interposer 22. As previously described with reference to FIG. 1, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26. In the embodiment of FIG. 2, a first outdiffusion-suppressing coating in the form of a first titanium (Ti) layer 30 is disposed on the first bond pad metal surface 10S of the first bond pad metal 10; and likewise a second outdiffusion-suppressing coating in the form of second titanium (Ti) layer 32 is disposed on the second bond pad metal surface 20S of the second bond pad metal 20. As indicated in FIG. 2, the first titanium layer 30 has a thickness d_{Ti} and the second titanium layer 32 has the same thickness d_{Ti}. In some nonlimiting illustrative embodiments, the thickness d_{Ti} is in a thickness range of 20 angstroms to 50 angstroms. The total thickness of the combined first and second titanium layers 30 and 32 is thus in a range of 40 angstroms to 100 angstroms. This thickness range provides a sufficient thickness to suppress copper outdiffusion, while also being sufficiently thin to interpose a negligible amount of electrical resistance across the electrical bond. It is noted that while in illustrative FIG. 2 both titanium layers 30 and 32 have the same thickness d_{Ti}, this is not required and in other embodiments it is contemplated for the two titanium layers 30 and 32 to have different thicknesses.

FIG. 2 diagrammatically shows the region of first bond pad metal 10 and the (nominally) aligned region of second bond pad metal 20 being laterally misaligned, e.g., similarly to the lateral misalignment distance D_{MA} indicated in the example of FIG. 1. The lateral misalignment distance may be 0%˜30% of the width of the bond pad metal 10 (or bond pad metal 20). Consequently, the second bond pad metal surface 20S does not fully cover the first bond pad metal surface 10S, and vice versa. However, as seen in FIG. 2, the first bond pad metal surface 10S is covered by the first titanium layer 30; and likewise, the second bond pad metal surface 20S is covered by the second titanium layer 32. Thus, copper outdiffusion 28 diagrammatically indicated in FIG. 1 during initial bonding or during in-service device operation due to applied electrical voltages is suppressed or eliminated. This reduces or eliminates the likelihood of copper outdiffusion-produced low electrical resistance or electrical shorting across the region R (see FIG. 1) of the adjacent regions of copper bond pad metal 10 and 20. This advantageously improves device performance, for example by increasing time-dependent dielectric breakdown (TDDB) corresponding to a longer time-to-failure. Additionally or alternatively, the suppression of copper outdiffusion by the titanium layers 30 and 32 can advantageously enable increased miniaturization of the electrical bonds, e.g., by reducing the bond spacing S_{B} (indicated in FIG. 1). With the titanium layers 30 and 32, lateral misalignment distance in a range of 0%˜30% of the width of the bond pad metal 10 (or bond pad metal 20) advantageously block the copper from diffusing out and adversely impacting yield or reliability performance.

The first and second titanium layers 30 and 32 may be formed by any suitable deposition process, such as physical vapor deposition (PVD), chemical vapor deposition (CVD), or the like. A further advantage of this approach for suppressing copper outdiffusion is that the same photolithography mask used to define the regions of first copper bond pad metal 10 can be used to define the area of the first titanium layer 30; and likewise, the same photolithography mask used to define the regions of second copper bond pad metal 20 can be used to define the area of the second titanium layer 32. This allows for the addition of the titanium layers 30 and 32 without significant increase in processing complexity.

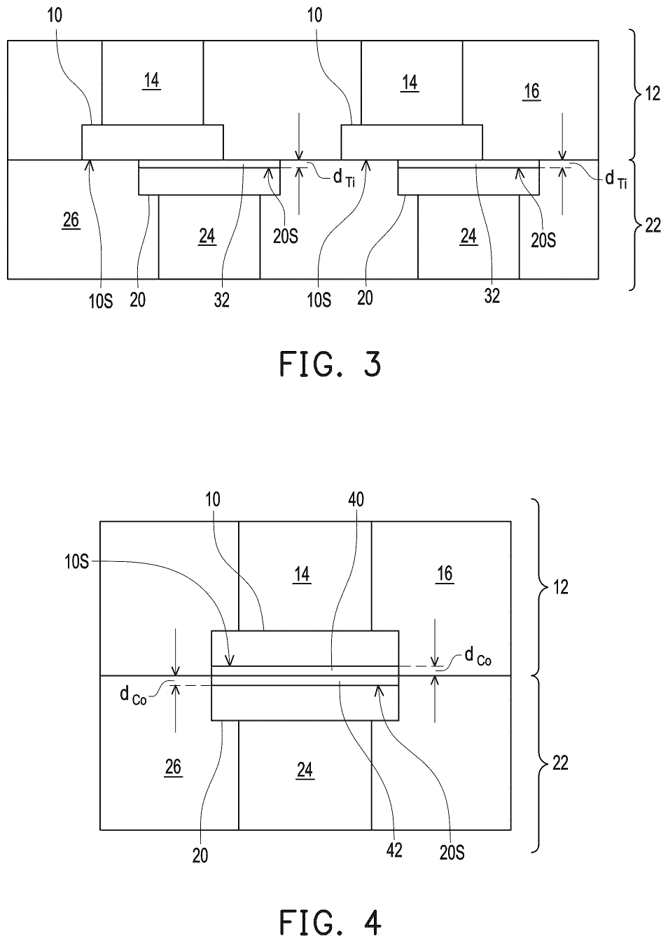

FIG. 3 illustrates, by way of a diagrammatic side sectional view, two representative electrical bonds between the first wafer or chip or interposer 12 and the second wafer or chip or interposer 22. As previously described, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26.

The embodiment of FIG. 3 differs from the embodiment of FIG. 2 in that the embodiment of FIG. 3 includes only the second outdiffusion-suppressing coating in the form of second titanium layer 32 is disposed on the second bond pad metal surface 20S of the second bond pad metal 20. The first titanium layer 30 is omitted in the embodiment of FIG. 3. The second titanium layer 32 has the thickness d_{Ti}, e.g. in a thickness range of 20 angstroms to 50 angstroms in some nonlimiting illustrative embodiments. This thickness range provides a sufficient thickness to suppress copper outdiffusion, while also being sufficiently thin to interpose a negligible amount of electrical resistance across the electrical bond. The second titanium layer 32 may be formed by any suitable deposition process, such as PVD, CVD, or the like, and again in some nonlimiting illustrative embodiments the same photolithography mask used to define the regions of second copper bond pad metal 20 can be used to define the area of the second titanium layer 32, thus allowing for the addition of the titanium layer 32 without significant increase in processing complexity.

FIG. 3 diagrammatically shows the two regions of first bond pad metal 10 and the (nominally) aligned respective two regions of second bond pad metal 20 being laterally misaligned, e.g., similarly to the lateral misalignment distance D_{MA} indicated in the example of FIG. 1. Consequently, the second bond pad metal surface 20S does not fully cover the first bond pad metal surface 10S, and vice versa. However, as seen in FIG. 3, the second bond pad metal surface 20S is covered by the second titanium layer 32. Unlike the embodiment of FIG. 2, due to the omission of the first titanium layer 30 the non-overlapping portion of the first bond pad metal surface 10S does not have this copper outdiffusion suppression. However, the suppression of copper outdiffusion from the second bond pad metal surface 20S still reduces or eliminates the likelihood of copper outdiffusion-produced low electrical resistance or electrical shorting across the illustrated two electrical bonds. This advantageously improves device performance, for example by increasing TDDB. Additionally or alternatively, the suppression of copper outdiffusion by the titanium layer 32 can advantageously enable increased miniaturization of the electrical bonds, e.g., by reducing the bond spacing S_{B}. The titanium layer 32 thus advantageously blocks copper outdiffusion to enable the lateral misalignment distance to be in a range of 0%˜30% of the width of the bond pad metal 10 (or bond pad metal 20) without adversely impacting yield or reliability performance.

The inclusion of the second titanium layer 32 and omission of the first titanium layer 30, as shown in FIG. 3, may be more effective in some embodiments than the reverse (i.e., retaining first titanium layer 30 and omitting second titanium layer 32). For example, consider an embodiment in which the second dielectric material or layer 26 is silicon oxynitride (SiON), and the first dielectric material or layer 16 is a high density plasma (HDP) dielectric such as undoped silicate glass (USG), or the like. Copper more easily diffuses in the HDP oxide 16, so the second titanium layer 32 operates to block this copper diffusion into the HDP oxide 16. In contrast, copper does not easily diffuse in the SiON 26, so the first titanium layer 30 can be omitted without introducing substantial copper diffusion into the SiON 26 in the case of a lateral misalignment.

FIG. 4 illustrates, by way of a diagrammatic side sectional view, a representative electrical bond between the first wafer or chip or interposer 12 and the second wafer or chip or interposer 22. As previously described with reference to FIG. 1, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26. In the embodiment of FIG. 4, a first outdiffusion-suppressing coating in the form of a first cobalt (Co) layer 40 is disposed on the first bond pad metal surface 10S of the first bond pad metal 10; and likewise a second outdiffusion-suppressing coating in the form of second cobalt (Co) layer 42 is disposed on the second bond pad metal surface 20S of the second bond pad metal 20. As indicated in FIG. 4, the first cobalt layer 40 has a thickness d_{Co} and the second cobalt layer 42 has the same thickness d_{Co}. In some nonlimiting illustrative embodiments, the thickness d_{Co} is in a thickness range of 20 angstroms to 50 angstroms. The total thickness of the combined first and second cobalt layers 40 and 42 is thus in a range of 40 angstroms to 100 angstroms. This thickness range provides a sufficient thickness to suppress copper outdiffusion, while also being sufficiently thin to interpose a negligible amount of electrical resistance across the electrical bond. It is noted that while in illustrative FIG. 4 both cobalt layers 40 and 42 have the same thickness d_{Co}, this is not required and in other embodiments it is contemplated for the two cobalt layers 40 and 42 to have different thicknesses.

If the region of first bond pad metal 10 and the (nominally) aligned region of second bond pad metal 20 are laterally misaligned, e.g., similarly to the lateral misalignment distance D_{MA} indicated in the example of FIG. 1, then the second bond pad metal surface 20S does not fully cover the first bond pad metal surface 10S, and vice versa. However, the first bond pad metal surface 10S is covered by the first cobalt layer 40; and likewise, the second bond pad metal surface 20S is covered by the second cobalt layer 42. Thus, copper outdiffusion 28 diagrammatically indicated in FIG. 1 during initial bonding or during in-service device operation due to applied electrical voltages is suppressed or eliminated. This reduces or eliminates the likelihood of copper outdiffusion-produced low electrical resistance or electrical shorting across the region R (see FIG. 1) of the adjacent regions of copper bond pad metal 10 and 20. This advantageously improves device performance, for example by increasing TDDB corresponding to a longer time-to-failure. Additionally or alternatively, the suppression of copper outdiffusion by the cobalt layers 40 and 42 can advantageously enable increased miniaturization of the electrical bonds, e.g., by reducing the bond spacing S_{B}. The cobalt layers 40 and 42 thus advantageously block copper outdiffusion to enable the lateral misalignment distance to be in a range of 0%˜30% of the width of the bond pad metal 10 (or bond pad metal 20) without adversely impacting yield or reliability performance.

The first and second cobalt layers 40 and 42 may be formed by any suitable deposition process, such as CVD or the like. A further advantage of this approach for suppressing copper outdiffusion is that a selective cobalt cap deposition process is used, without any photolithography mask, to define the first cobalt layer 40; and likewise, that a selective cobalt cap deposition process is used, without any photolithography mask, to define the second cobalt layer 42. This allows for the addition of the cobalt layers 40 and 42 without significant increase in processing complexity.

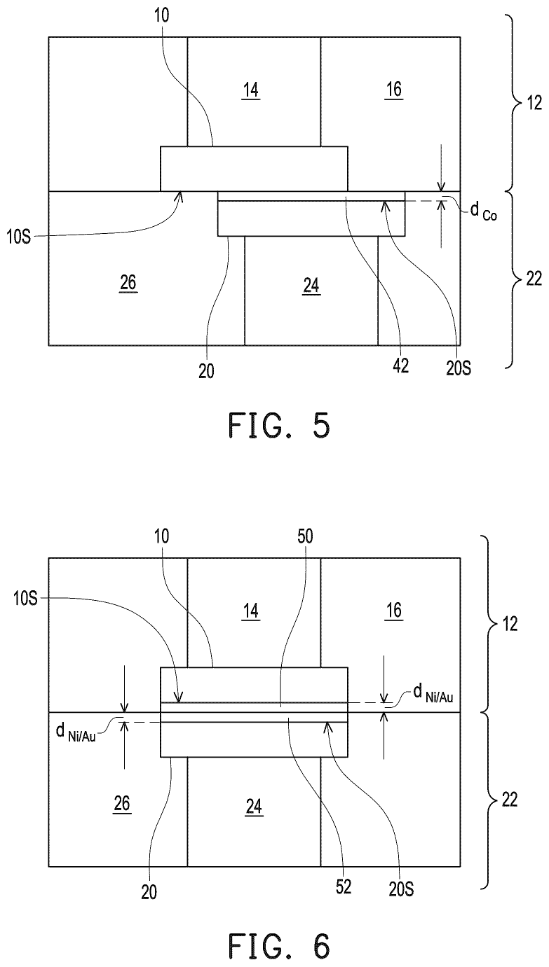

FIG. 5 illustrates, by way of a diagrammatic side sectional view, a representative electrical bond between the first wafer or chip or interposer 12 and the second wafer or chip or interposer 22. As previously described, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26.

The embodiment of FIG. 5 differs from the embodiment of FIG. 4 in that the embodiment of FIG. 5 includes only the second outdiffusion-suppressing coating in the form of second cobalt layer 42 is disposed on the second bond pad metal surface 20S of the second bond pad metal 20. The first cobalt layer 40 is omitted in the embodiment of FIG. 5. The second cobalt layer 42 has the thickness d_{Co}, e.g. in a thickness range of 20 angstroms to 50 angstroms in some nonlimiting illustrative embodiments. This thickness range provides a sufficient thickness to suppress copper outdiffusion, while also being sufficiently thin to interpose a negligible amount of electrical resistance across the electrical bond. The second cobalt layer 42 may be formed by any suitable deposition process, such as CVD or the like, and again in some nonlimiting illustrative embodiments a selective cobalt cap deposition process is used, without any photolithography mask, to define the area of the second cobalt layer 42, thus allowing for the addition of the cobalt layer 42 without significant increase in processing complexity.

If the regions of first bond pad metal 10 and the (nominally) aligned respective regions of second bond pad metal 20 are laterally misaligned, e.g., similarly to the lateral misalignment distance D_{MA} indicated in the example of FIG. 1, then the second bond pad metal surface 20S does not fully cover the first bond pad metal surface 10S, and vice versa. However, as seen in FIG. 5, the second bond pad metal surface 20S is covered by the second cobalt layer 42. Unlike the embodiment of FIG. 4, due to the omission of the first cobalt layer 40 the non-overlapping portion of the first bond pad metal surface 10S does not have this copper outdiffusion suppression. However, the suppression of copper outdiffusion from the second bond pad metal surface 20S still reduces or eliminates the likelihood of copper outdiffusion-produced low electrical resistance or electrical shorting across the illustrated two electrical bonds. This advantageously improves device performance, for example by increasing TDDB. Additionally or alternatively, the suppression of copper outdiffusion by the cobalt layer 42 can advantageously enable increased miniaturization of the electrical bonds, e.g., by reducing the bond spacing S_{B}. The cobalt layer 42 thus advantageously blocks copper outdiffusion to enable the lateral misalignment distance to be in a range of 0%˜30% of the width of the bond pad metal 10 (or bond pad metal 20) without adversely impacting yield or reliability performance.

The inclusion of the second cobalt layer 42 and omission of the first cobalt layer 40, as shown in FIG. 5, may be more effective in some embodiments than the reverse (i.e., retaining first cobalt layer 40 and omitting second cobalt layer 42). For example, consider an embodiment in which the second dielectric material or layer 26 is SiON, and the first dielectric material or layer 16 is a HDP dielectric. Copper more easily diffuses in the HDP oxide 16, so the second cobalt layer 42 operates to block this copper diffusion into the HDP oxide 16. In contrast, copper does not easily diffuse in the SiON 26, so the first cobalt layer 40 can be omitted without introducing substantial copper diffusion into the SiON 26 in the case of a lateral misalignment.

The example embodiments of FIGS. 2-5 employ a copper outdiffusion suppressing coating in the form of a titanium layer (FIGS. 2 and 3) or a cobalt layer (FIGS. 4 and 5). More generally, it is contemplated to employ another suitable metal layer or layers (other than a copper layer or layers) as the copper outdiffusion suppressing coating to provide a suitable barrier to copper outdiffusion during initial bonding or during in-service device operation due to applied electrical voltages, thus enabling lateral misalignment in a range of 0%˜30% of the width of the bond pad metal 10 (or bond pad metal 20) without adversely impacting yield or reliability performance.

FIG. 6 illustrates, by way of a diagrammatic side sectional view, a representative electrical bond between the first wafer or chip or interposer 12 and the second wafer or chip or interposer 22. As previously described with reference to FIG. 1, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26. In the embodiment of FIG. 4, a first outdiffusion-suppressing coating in the form of a first nickel/gold (Ni/Au) layer 50 is disposed on the first bond pad metal surface 10S of the first bond pad metal 10; and likewise a second outdiffusion-suppressing coating in the form of second nickel/gold (Ni/Au) layer 52 is disposed on the second bond pad metal surface 20S of the second bond pad metal 20. As indicated in FIG. 6, the first nickel/gold layer 50 has a thickness dxi/Au and the second cobalt layer 42 has the same thickness dxi/Au. In some nonlimiting illustrative embodiments, the thickness dxi/Au is in a thickness range of 0.05 micron to 1 micron. The total thickness of the combined first and second cobalt layers 50 and 52 is thus in a range of 0.1 micron to 2 microns. This thickness range provides a sufficient thickness to suppress copper outdiffusion, while also being sufficiently thin to interpose a negligible amount of electrical resistance across the electrical bond. It is noted that while in illustrative FIG. 6 both nickel/gold layers 50 and 52 have the same thickness dxi/Au, this is not required and in other embodiments it is contemplated for the two nickel/gold layers 50 and 52 to have different thicknesses.

If the region of first bond pad metal 10 and the (nominally) aligned region of second bond pad metal 20 are laterally misaligned, e.g., similarly to the lateral misalignment distance D_{MA} indicated in the example of FIG. 1, then the second bond pad metal surface 20S does not fully cover the first bond pad metal surface 10S, and vice versa. However, the first bond pad metal surface 10S is covered by the first nickel/gold layer 50; and likewise, the second bond pad metal surface 20S is covered by the second nickel/gold layer 52. Thus, copper outdiffusion 28 diagrammatically indicated in FIG. 1 during initial bonding or during in-service device operation due to applied electrical voltages is suppressed or eliminated. This reduces or eliminates the likelihood of copper outdiffusion-produced low electrical resistance or electrical shorting across the region R (see FIG. 1) of the adjacent regions of copper bond pad metal 10 and 20. This advantageously improves device performance, for example by increasing TDDB corresponding to a longer time-to-failure. Additionally or alternatively, the suppression of copper outdiffusion by the nickel/gold layers 50 and 52 can advantageously enable increased miniaturization of the electrical bonds, e.g., by reducing the bond spacing S_{B}. The nickel/gold layers 50 and 52 thus advantageously block copper outdiffusion to enable the lateral misalignment distance to be in a range of 0%˜30% of the width of the bond pad metal 10 (or bond pad metal 20) without adversely impacting yield or reliability performance.

The first and second nickel/gold layers 50 and 52 may be formed in some nonlimiting illustrative embodiments by an electroless nickel immersion gold (ENIG) process. A further advantage of this approach for suppressing copper outdiffusion is that no photolithography mask is required to define the area of the first nickel/gold layer 50; and likewise, no photolithography mask is required to define the area of the second nickel/gold layer 52. This allows for the addition of the nickel/gold layer 50 and 52 without significant increase in processing complexity.

In one nonlimiting illustrative example, the ENIG process for forming the nickel/gold layers 50 and 52 may be as follows. A pretreatment may be performed, such as (in one nonlimiting illustrative example) a sequence of oil removal, water washing, pickling, water washing, micro-etching, water washing, and pre-soaking in an acid such as sulfuric acid (H₂SO₄). The pretreatment is followed by activation using a palladium (Pd) catalyst, water washing, chemical nickel (Ni), water washing, immersion gold plating, gold recovery, water washing, and drying. This is merely an illustrative example.

In one variant embodiment, the layers 50 and 52 may be Ni/Pd/Au layers, where a chemical palladium (Pd) layer is applied on the nickel before the immersion gold plating, so that the layers 50 and 52 are nickel/palladium/gold (Ni/Pd/Au) layers. This is thus an electroless nickel electroless palladium immersion gold (ENEPIG) process.

It is also contemplated to deposit the nickel/gold layers 50 and 52 by a process other than an ENIG process, such as by vacuum evaporation.

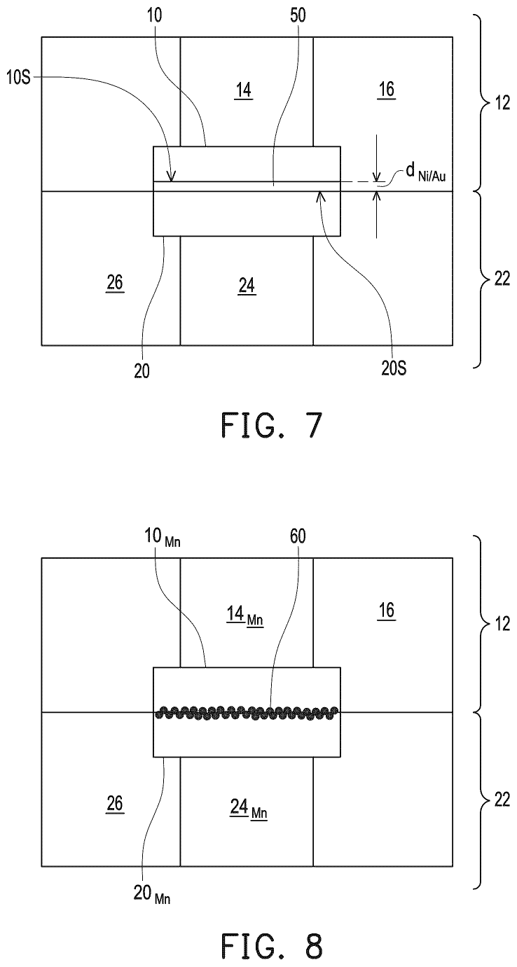

FIG. 7 illustrates, by way of a diagrammatic side sectional view, a representative electrical bond between the first wafer or chip or interposer 12 and the second wafer or chip or interposer 22. As previously described, the first wafer or chip or interposer 12 includes first bond pad metal 10 with first bond pad metal surface 10S, and first bond pad via 14. The first bond pad metal 10 and the first bond pad via 14 are embedded in first dielectric material or layer 16. Likewise, the second wafer or chip or interposer 22 includes second bond pad metal 20 with second bond pad metal surface 20S, and second bond pad via 24. The second bond pad metal 20 and the second bond pad via 24 are embedded in second dielectric material or layer 26.

The embodiment of FIG. 7 differs from the embodiment of FIG. 6 in that the embodiment of FIG. 7 includes only the first outdiffusion-suppressing coating in the form of first nickel/gold layer 50 is disposed on the first bond pad metal surface 10S of the first bond pad metal 10. The second nickel/gold layer 52 is omitted in the embodiment of FIG. 7. The first nickel/gold layer 50 has the thickness dxi/Au, e.g. in a thickness range of 0.05 micron to 1 micron in some nonlimiting illustrative embodiments. This thickness range provides a sufficient thickness to suppress copper outdiffusion, while also being sufficiently thin to interpose a negligible amount of electrical resistance across the electrical bond. The first nickel/gold layer 50 may be formed by an ENIG process. In a variant embodiment, the layer 50 may be a nickel/palladium/gold (Ni/Pd/Au) layer formed by an ENEPIG process. In some nonlimiting illustrative embodiments no photolithography mask is required to define the area of the nickel/gold layer 50, thus allowing for the addition of the nickel/gold layer 50 without significant increase in processing complexity.

If the regions of first bond pad metal 10 and the (nominally) aligned respective regions of second bond pad metal 20 are laterally misaligned, e.g., similarly to the lateral misalignment distance D_{MA} indicated in the example of FIG. 1, then the second bond pad metal surface 20S does not fully cover the first bond pad metal surface 10S, and vice versa. However, in such a lateral misalignment the first bond pad metal surface 10S is covered by the first nickel/gold layer 50. Unlike the embodiment of FIG. 6, due to the omission of the second nickel/gold layer 52 the non-overlapping portion of the second bond pad metal surface 20S does not have this copper outdiffusion suppression. However, the suppression of copper outdiffusion from the first bond pad metal surface 10S still reduces or eliminates the likelihood of copper outdiffusion-produced low electrical resistance or electrical shorting across the illustrated two electrical bonds. This advantageously improves device performance, for example by increasing TDDB. Additionally or alternatively, the suppression of copper outdiffusion by the nickel/gold layer 50 can advantageously enable increased miniaturization of the electrical bonds, e.g., by reducing the bond spacing S_{B}. The nickel/gold layer 50 thus advantageously blocks copper outdiffusion to enable the lateral misalignment distance to be in a range of 0%˜30% of the width of the bond pad metal 10 (or bond pad metal 20) without adversely impacting yield or reliability performance.

With reference to FIG. 8, in some embodiments suppression of copper outdiffusion is provided by doping the copper of the copper bond pad metals (and optionally also of the copper bond pad vias) with a dopant that surface-segregates and oxidizes to form a metal oxide barrier at the copper bond pad metal surfaces 10S and 20S. FIG. 8 illustrates, by way of a diagrammatic side sectional view, a representative electrical bond between the first wafer or chip or interposer 12 and the second wafer or chip or interposer 22. The first wafer or chip or interposer 12 includes first bond pad metal 10_{Mn} comprising copper doped with manganese (Mn), and first bond pad via 14_{Mn} also comprising copper doped with manganese. The first bond pad metal 10_{Mn} and the first bond pad via 14_{Mn} are embedded in first dielectric material or layer 16. Likewise, the second wafer or chip or interposer 22 includes second bond pad metal 20_{Mn} comprising copper doped with manganese, and second bond pad via 24_{Mn} comprising copper doped with manganese. The second bond pad metal 20_{Mn} and the second bond pad via 24_{Mn} are embedded in second dielectric material or layer 26.

As diagrammatically indicated in FIG. 8, the manganese dopant tends to surface segregate, and at the exposed surfaces of the first and second bond pad metal 10_{Mn} and 20_{Mn} the surface-segregated manganese oxidizes to form a copper outdiffusion-suppressing layer or layers of manganese oxide (MnO) 60. This layer(s) of manganese oxide 60 blocks copper outdiffusion if the regions of first and second bond pad metal 10_{Mn} and 20_{Mn} are laterally misaligned during the bonding, e.g., similarly to the lateral misalignment distance D_{MA} indicated in the example of FIG. 1. In such a case, the manganese oxide layer or layers 60 suppresses copper outdiffusion from the non-overlapping portions of the facing surfaces of the (mis) aligned regions of first and second bond pad metal 10_{Mn} and 20_{Mn}. Thus, copper outdiffusion 28 diagrammatically indicated in FIG. 1 during initial bonding or during in-service device operation due to applied electrical voltages is suppressed or eliminated. This reduces or eliminates the likelihood of copper outdiffusion-produced low electrical resistance or electrical shorting across the region R (see FIG. 1) of the adjacent regions of copper bond pad metal 10_{Mn} and 20_{Mn}. This advantageously improves device performance, for example by increasing TDDB corresponding to a longer time-to-failure. Additionally or alternatively, the suppression of copper outdiffusion by the manganese oxide layer(s) 60 can advantageously enable increased miniaturization of the electrical bonds, e.g., by reducing the bond spacing S_{B} (indicated in FIG. 1). In some nonlimiting illustrative embodiments, the copper bond pad metal 10_{Mn} and 20_{Mn} and the copper bond pad vias 14_{Mn} and 24_{Mn} are doped with about 0.5% to 2% manganese to provide sufficient manganese for formation of the copper outdiffusion-suppressing manganese oxide layer(s) 60. In experiments, manganese doping in this range provided desirable TDDB with negligible change in electrical conductivity of the electrical connection. The copper outdiffusion-suppressing manganese oxide layer(s) 60 thus advantageously block copper outdiffusion to enable the lateral misalignment distance to be in a range of 0%˜30% of the width of the bond pad metal 10_{Mn} (or bond pad metal 20_{Mn}) without adversely impacting yield or reliability performance.

In the illustrative embodiment, both the copper bond pad metal 10_{Mn} and 20_{Mn} and the copper bond pad vias 14_{Mn} and 24_{Mn} are doped with manganese. However, in a variant embodiment, it is contemplated for only the copper bond pad metal 10_{Mn} and 20_{Mn} to be doped with manganese, with the copper bond pad vias being undoped copper. In this case, the first copper bond pad metal 10_{Mn} comprises copper doped with manganese and has a first copper bond pad metal surface comprising manganese oxide 60. The second copper bond pad metal is suitably undoped copper (e.g., same as the copper bond pad metal 20 of previous embodiments). The first copper bond pad metal surface and the second copper bond pad metal surface are bonded together to form an electrical connection between the first semiconductor wafer or chip or interposer 12 and the second semiconductor wafer or chip or interposer 22.

In the illustrative example of FIG. 8, the copper bond pad metal 10_{Mn} and 20_{Mn} (and optionally also the copper bond pad vias 14_{Mn} and 24_{Mn}) are doped with manganese to provide the copper outdiffusion suppressing metal oxide (here, manganese oxide) layer 60. However, it is contemplated to employ other dopants besides manganese for this purpose. The employed metal dopant should have a suitable tendency to surface-segregate and oxidize to form a copper outdiffusion-suppressing oxide layer similar to the manganese oxide layer 60 of the embodiment of FIG. 8.

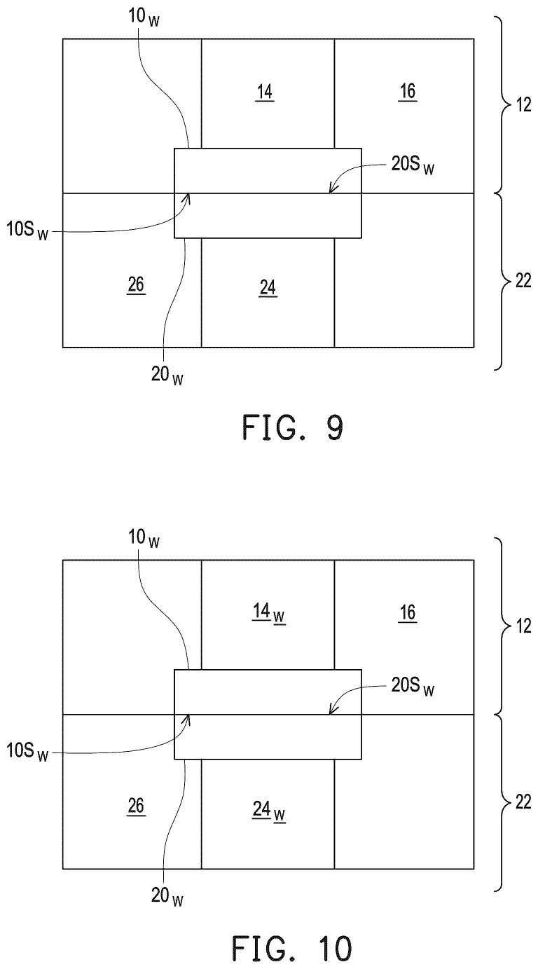

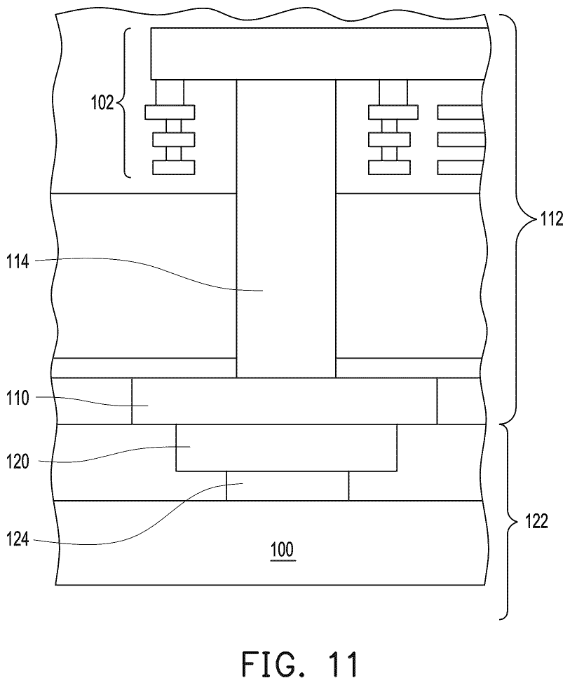

With reference to FIGS. 9 and 10, in some embodiments suppression of copper outdiffusion is provided by forming the bond pad metal of a metal other than copper.

FIG. 9 illustrates, by way of a diagrammatic side sectional view, a representative electrical bond between the first wafer or chip or interposer 12 and the second wafer or chip or interposer 22. The first wafer or chip or interposer 12 includes first bond pad metal 10_{W} comprising tungsten (W), and first bond pad via 14 comprising copper. The tungsten first bond pad metal 10_{W} and the first bond pad via 14 are embedded in first dielectric material or layer 16. Likewise, the second wafer or chip or interposer 22 includes second bond pad metal 20_{W} comprising tungsten, and second bond pad via 24 comprising copper. The tungsten second bond pad metal 20_{W} and the second bond pad via 24 are embedded in second dielectric material or layer 26. In this embodiment, a surface 10S_{W} of the tungsten first bond pad metal 10_{W} and a surface 20S_{W} of the tungsten second bond pad metal 20_{W} do not contain copper, and hence the problem of copper outdiffusion during initial bonding or during in-service device operation due to applied electrical voltages is eliminated.

FIG. 10 illustrates, by way of a diagrammatic side sectional view, a representative electrical bond between the first wafer or chip or interposer 12 and the second wafer or chip or interposer 22. The first wafer or chip or interposer 12 includes first bond pad metal 10_{W} comprising tungsten (W), and first bond pad via 14_{W} also comprising tungsten. The tungsten first bond pad metal 10_{W} and the tungsten first bond pad via 14_{W} are embedded in first dielectric material or layer 16. Likewise, the second wafer or chip or interposer 22 includes second bond pad metal 20_{W} comprising tungsten, and second bond pad via 24_{W} also comprising tungsten. The tungsten second bond pad metal 20_{W} and the tungsten second bond pad via 24_{W} are embedded in second dielectric material or layer 26. In this embodiment, surface 10S_{W} of the tungsten first bond pad metal 10_{W} and surface 20S_{W} of the tungsten second bond pad metal 20_{W} do not contain copper, and hence the problem of copper outdiffusion during initial bonding or during in-service device operation due to applied electrical voltages is eliminated.

The disclosed copper outdiffusion-suppressing electrical bonds between a first semiconductor wafer or chip or interposer 12 and a second semiconductor wafer or chip or interposer 22 can be employed in a wide range of semiconductor wafer and/or chip stacks such as CoW packages, WoW packages, CoWoS packages, InFO packages, PoP packages, SoIC packages, and the like. Some nonlimiting illustrative examples of electrical bond implementations in which the disclosed copper outdiffusion-suppressing electrical bonds can be utilized are illustrated in FIGS. 11-13.

FIG. 11 illustrates, by way of a diagrammatic side sectional view, a representative electrical bond between the first wafer or chip or interposer 112 and a second wafer or chip or interposer 122. The representative electrical bond includes a region of first bond pad metal 110 connected to a first bond pad via 114 which in the example of FIG. 11 is a through-silicon via (TSV) 114. The first bond pad metal 110 and TSV 114 are included in the first wafer or chip or interposer 112. The representative electrical bond further includes a region of second bond pad metal 120 connected to a second bond pad via 124 which in the example of FIG. 11 electrically connects the second bond pad metal 120 with an aluminum pad 100. The second bond pad metal 120 and second bond pad via 124 are included in the second wafer or chip or interposer 122. In the example of FIG. 11, the TSV 114 connects with one or more metallization layers 102 disposed on a first side of the first wafer or chip or interposer 112 with the first bond pad metal 110 disposed on an opposite second side of the first wafer or chip or interposer 112.

In some embodiments, the first bond pad metal 110 and second bond pad metal 120 may include a copper outdiffusion-suppressing coating (not shown in FIG. 11) on the first copper bond pad metal surface and/or on the second copper bond pad metal surface, where the outdiffusion-suppressing coating may by way of some nonlimiting illustrative examples be: a titanium (Ti) layer or layers 30 and/or 32 as per the embodiment of FIG. 2 or the embodiment of FIG. 3; a cobalt layer or layers 40 and/or 42 as per the embodiment of FIG. 4 or the embodiment of FIG. 5; a nickel/gold layer or layers 50 and/or 52 (or, in a variant, a nickel/palladium/gold layer or layers) as per the embodiment of FIG. 6 or the embodiment of FIG. 7.

In some embodiments, the first bond pad metal 110 and second bond pad metal 120 may comprise copper with manganese doping forming a copper outdiffusion-suppressing manganese oxide layer 60 as per the embodiment of FIG. 8.

In some embodiments, the first bond pad metal 110 and second bond pad metal 120 may be tungsten pads 10_{W} and 20_{W}, as per the embodiment of FIG. 9 or the embodiment of FIG. 10.

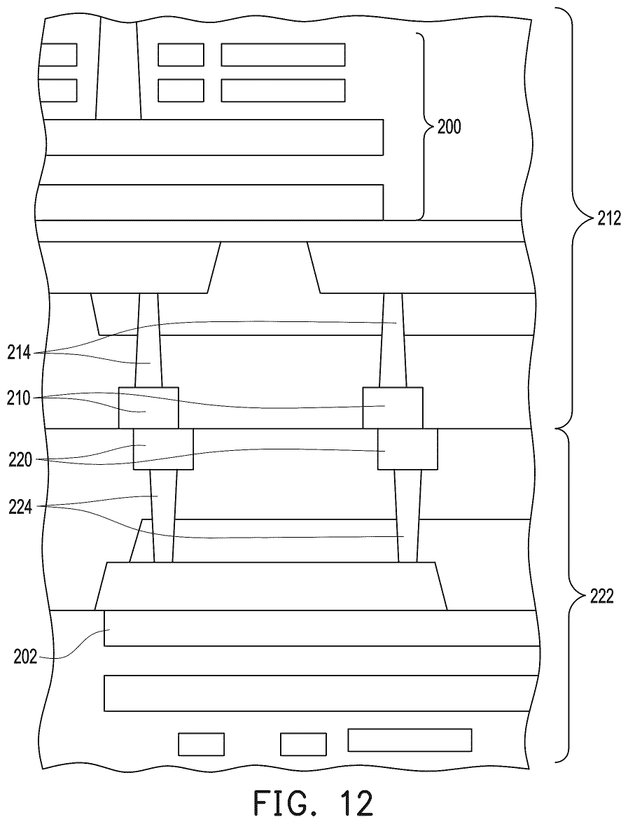

FIG. 12 illustrates, by way of a diagrammatic side sectional view, a representative electrical bond between the first wafer or chip or interposer 212 and a second wafer or chip or interposer 222. The representative electrical bond includes a region of first bond pad metal 210 connected to a first bond pad via 214 which in the example of FIG. 12 connects with one or more metallization layers 200. The first bond pad metal 210 and first bond pad via 214 are included in the first wafer or chip or interposer 212. The representative electrical bond further includes a region of second bond pad metal 220 connected to a second bond pad via 224 which in the example of FIG. 12 electrically connects the second bond pad metal 220 with an aluminum pad 202. The second bond pad metal 220 and second bond pad via 224 are included in the second wafer or chip or interposer 222.

In some embodiments, the first bond pad metal 210 and second bond pad metal 220 may include a copper outdiffusion-suppressing coating (not shown in FIG. 12) on the first copper bond pad metal surface and/or on the second copper bond pad metal surface, where the outdiffusion-suppressing coating may by way of some nonlimiting illustrative examples be: a titanium (Ti) layer or layers 30 and/or 32 as per the embodiment of FIG. 2 or the embodiment of FIG. 3; a cobalt layer or layers 40 and/or 42 as per the embodiment of FIG. 4 or the embodiment of FIG. 5; a nickel/gold layer or layers 50 and/or 52 (or, in a variant, a nickel/palladium/gold layer or layers) as per the embodiment of FIG. 6 or the embodiment of FIG. 7.

In some embodiments, the first bond pad metal 210 and second bond pad metal 220 may comprise copper with manganese doping forming a copper outdiffusion-suppressing manganese oxide layer 60 as per the embodiment of FIG. 8.

In some embodiments, the first bond pad metal 210 and second bond pad metal 220 may be tungsten pads 10_{W} and 20_{W}, as per the embodiment of FIG. 9 or the embodiment of FIG. 10.

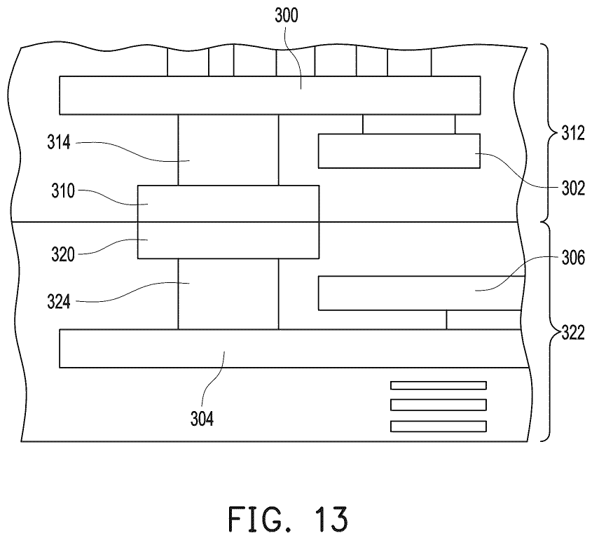

FIG. 13 illustrates, by way of a diagrammatic side sectional view, a representative electrical bond between the first wafer or chip or interposer 312 and a second wafer or chip or interposer 322. The representative electrical bond includes a region of first bond pad metal 310 connected to a first bond pad via 314 which in the example of FIG. 13 connects by way of one or more metallization layers 300 with an aluminum pad 302 of the first wafer or chip or interposer 312. The first bond pad metal 310 and first bond pad via 314 are included in the first wafer or chip or interposer 312. The representative electrical bond further includes a region of second bond pad metal 320 connected to a second bond pad via 324 which in the example of FIG. 13 connects by way of one or more metallization layers 304 with an aluminum pad 306 of the second wafer or chip or interposer 322. The second bond pad metal 320 and second bond pad via 324 are included in the second wafer or chip or interposer 322.

In some embodiments, the first bond pad metal 310 and second bond pad metal 320 may include a copper outdiffusion-suppressing coating (not shown in FIG. 13) on the first copper bond pad metal surface and/or on the second copper bond pad metal surface, where the outdiffusion-suppressing coating may by way of some nonlimiting illustrative examples be: a titanium (Ti) layer or layers 30 and/or 32 as per the embodiment of FIG. 2 or the embodiment of FIG. 3; a cobalt layer or layers 40 and/or 42 as per the embodiment of FIG. 4 or the embodiment of FIG. 5; a nickel/gold layer or layers 50 and/or 52 (or, in a variant, a nickel/palladium/gold layer or layers) as per the embodiment of FIG. 6 or the embodiment of FIG. 7.

In some embodiments, the first bond pad metal 310 and second bond pad metal 320 may comprise copper with manganese doping forming a copper outdiffusion-suppressing manganese oxide layer 60 as per the embodiment of FIG. 8.

In some embodiments, the first bond pad metal 310 and second bond pad metal 320 may be tungsten pads 10_{W} and 20_{W}, as per the embodiment of FIG. 9 or the embodiment of FIG. 10.

It will be appreciated that FIGS. 11-13 present some nonlimiting illustrative examples, and that more generally the various embodiments of copper outdiffusion-suppressing electrical bonds between a first semiconductor wafer or chip or interposer and a second semiconductor wafer or chip or interposer as disclosed herein can be employed in substantially any electrical connection between wafers, chips, or interposers of a semiconductor wafer and/or chip stack.

In the following, some further embodiments are described.

In a nonlimiting illustrative embodiment, a semiconductor packaging method is disclosed of bonding a first semiconductor wafer or chip or interposer and a second semiconductor wafer or chip or interposer, the method comprising: forming first bond pad metal with a first bond pad metal surface on the first semiconductor wafer or chip or interposer; forming second bond pad metal with a second bond pad metal surface on the second semiconductor wafer or chip or interposer; disposing an outdiffusion-suppressing coating on the first bond pad metal surface and/or on the second bond pad metal surface; and after the disposing, bonding the first bond pad metal surface and the second bond pad metal surface together to form an electrical connection between the first semiconductor wafer or chip or interposer and the second semiconductor wafer or chip or interposer.

In a nonlimiting illustrative embodiment, a semiconductor packaging method is disclosed of bonding a first semiconductor wafer or chip or interposer and a second semiconductor wafer or chip or interposer, the method comprising: forming first copper bond pad metal comprising copper doped with manganese on the first semiconductor wafer or chip or interposer, the first copper bond pad metal having a first copper bond pad metal surface comprising manganese oxide; forming second copper bond pad metal with a second copper bond pad metal surface on the second semiconductor wafer or chip or interposer; and bonding the first copper bond pad metal surface and the second copper bond pad metal surface together to form an electrical connection between the first semiconductor wafer or chip or interposer and the second semiconductor wafer or chip or interposer.

In a nonlimiting illustrative embodiment, an electrical bond between a first semiconductor wafer or chip or interposer and a second semiconductor wafer or chip or interposer of a semiconductor package is disclosed. The electrical bond comprises a first bond pad metal with a first bond pad metal surface disposed on the first semiconductor wafer or chip or interposer, the first bond pad metal comprising tungsten, and a second bond pad metal with a second bond pad metal surface disposed on the second semiconductor wafer or chip or interposer, the second bond pad metal comprising tungsten. The first bond pad metal surface and the second bond pad metal surface are bonded together.

In a nonlimiting illustrative embodiment, a copper diffusion-suppressing electrical bond between a first semiconductor wafer or chip or interposer and a second semiconductor wafer or chip or interposer includes a first bond pad metal with a first bond pad metal surface disposed on the first semiconductor wafer or chip or interposer, bonded with a second bond pad metal with a second bond pad metal surface disposed on the second semiconductor wafer or chip or interposer. A copper outdiffusion-suppressing coating such as a titanium, cobalt, nickel/gold, or nickel/palladium/gold layer may be disposed on the first copper bond pad metal surface and/or on the second copper bond pad metal surface. The copper of the bond pad metal may be doped with manganese to form a copper outdiffusion-suppressing surface manganese oxide. The bond pad metal may alternatively be tungsten to prevent copper outdiffusion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor packaging method of bonding a first semiconductor wafer or chip or interposer and a second semiconductor wafer or chip or interposer, the method comprising:
forming first bond pad metal with a first bond pad metal surface on the first semiconductor wafer or chip or interposer;
forming second bond pad metal with a second bond pad metal surface on the second semiconductor wafer or chip or interposer;
disposing an outdiffusion-suppressing coating on the first bond pad metal surface and/or on the second bond pad metal surface; and
after the disposing, bonding the first bond pad metal surface and the second bond pad metal surface together to form an electrical connection between the first semiconductor wafer or chip or interposer and the second semiconductor wafer or chip or interposer.

2. The method of claim 1, wherein the first bond pad metal is copper and the first bond pad metal surface is a copper surface, and the disposing of the outdiffusion-suppressing coating includes:
disposing a copper outdiffusion-suppressing coating on the first copper bond pad metal surface.

3. The method of claim 2, wherein the second bond pad metal is copper and the second bond pad metal surface is a copper surface.

4. The method of claim 3, wherein the disposing of the outdiffusion-suppressing coating further includes:
disposing a copper outdiffusion-suppressing coating on the second copper bond pad metal surface.

5. The method of claim 2, wherein the copper outdiffusion-suppressing coating comprises at least one of a titanium layer, a cobalt layer, a nickel/gold layer, a nickel/palladium/gold layer, and a combination thereof.

6. The method of claim 1, wherein the disposing of the outdiffusion-suppressing coating on the first bond pad metal surface and/or on the second bond pad metal surface includes disposing the outdiffusion-suppressing coating on only one of the first bond pad metal surface or the second bond pad metal surface.

7. The method of claim 1, wherein:
the first bond pad metal is copper and the first bond pad metal surface is a copper surface; and
the outdiffusion-suppressing coating comprises a titanium or cobalt layer disposed on at least the first bond pad metal surface;
wherein the titanium or cobalt layer disposed on the first bond pad metal surface has a thickness in a thickness range of 20 angstroms to 50 angstroms.

8. The method of claim 1, wherein the disposing of the outdiffusion-suppressing coating includes:
performing an electroless nickel immersion gold (ENIG) process to form a nickel/gold layer on the first bond pad metal surface and/or on the second bond pad metal surface.

9. The method of claim 1, wherein the disposing of the outdiffusion-suppressing coating includes:
performing an electroless nickel electroless palladium immersion gold (ENEPIG) process to form a nickel/palladium/gold layer on the first bond pad metal surface and/or on the second bond pad metal surface.

10. The method of claim 1, wherein the bonding the of first bond pad metal surface and the second bond pad metal surface together to form the electrical connection includes bonding the first bond pad metal surface and the second bond pad metal surface together with a lateral offset of between 0-30% of a width of the first bond pad metal.

11. The method of claim 1, wherein:
the first and/or second bond pad metal surface on which the outdiffusion-suppressing coating is disposed is a copper surface; and
the outdiffusion-suppressing coating comprises a metal layer other than a copper layer.

12. The method of claim 1, wherein:
the first bond pad metal is electrically connected with an aluminum pad or a metallization layer or a through-silicon via of the first semiconductor wafer or chip or interposer; and
the second bond pad metal is electrically connected with an aluminum pad or a metallization layer or a through-silicon via of the second semiconductor wafer or chip or interposer.

13. A semiconductor packaging method of bonding a first semiconductor wafer or chip or interposer and a second semiconductor wafer or chip or interposer, the method comprising:
forming first bond pad metal on the first semiconductor wafer or chip or interposer, the first bond pad metal having a first bond pad metal surface;
forming second bond pad metal with a second bond pad metal surface on the second semiconductor wafer or chip or interposer; and
bonding the first bond pad metal surface and the second bond pad metal surface together to form an electrical connection between the first semiconductor wafer or chip or interposer and the second semiconductor wafer or chip or interposer.

14. The method of claim 13, wherein the forming of the first bond pad metal with the first bond pad metal surface comprises:
forming the first bond pad metal comprising copper doped with manganese on the first semiconductor wafer or chip or interposer, the first bond pad metal surface comprising manganese oxide.

15. The method of claim 14, wherein the second bond pad metal comprises copper.

16. The method of claim 15, wherein the forming of the second bond pad metal with the second bond pad metal surface comprises:
forming the second bond pad metal comprising copper doped with manganese on the second semiconductor wafer or chip or interposer, the second bond pad metal surface comprising manganese oxide.

17. The method of claim 14, wherein the first copper bond pad metal comprises copper doped with between 0.5% and 2% manganese.

18. An electrical bond between a first semiconductor wafer or chip or interposer and a second semiconductor wafer or chip or interposer of a semiconductor package, the electrical bond comprising:
a first bond pad metal with a first bond pad metal surface disposed on the first semiconductor wafer or chip or interposer; and
a second bond pad metal with a second bond pad metal surface disposed on the second semiconductor wafer or chip or interposer;
wherein the first bond pad metal surface and the second bond pad metal surface are bonded together.

19. The electrical bond of claim 18, wherein the first bond pad metal comprises tungsten, and the second bond pad metal comprises tungsten.

20. The electrical bond of claim 19, further comprising:
a first via comprising tungsten or copper disposed in the first semiconductor wafer or chip or interposer and connected with the first bond pad metal comprising tungsten; and
a second via comprising tungsten or copper disposed in the second semiconductor wafer or chip or interposer and connected with the second bond pad metal comprising tungsten.
